(19) United States
(12) Patent Application Publication
(10) Pub. No.: US 2007/0217151 A1
(43) Pub. Date: Sep. 20, 2007

(54) Heat dissipation structure for processors

(76) Inventor: Hung-Ming Lin, Taipei City (TW)

Correspondence Address: RABIN & Berdo, PC, 1101 14TH STREET, NW, SUITE 500, WASHINGTON, DC, 20005, US

(21) Appl. No.: 11/447,885

(22) Filed: Jun. 7, 2006

(30) Foreign Application Priority Data
Mar. 17, 2006 (TW) 095109347

(51) Int. Cl. H05K 7/20

(52) U.S. Cl. 361/697

(57) ABSTRACT

A heat dissipation structure for processors to disperse heat from a plurality of processors located on a main board includes a fastening element and a heat dissipator. The fastening element has a plurality of engaging members located on the main board corresponding to the processors. The heat dissipator is made of fine heat conductor and includes a radiator, a plurality of engaging portions and a plurality of coupling portions. The engaging portions correspond to the fastening element. The coupling portions correspond to the processors. The engaging portions of the heat dissipator are coupled with the corresponding engaging members of the fastening element and the coupling portions are in contact with the corresponding processors.

### BACKGROUND OF THE INVENTION

1. Field of Invention

The invention relates to a heat dissipation structure for multiple processors and is particularly to a heat dissipation structure to disperse heat for a plurality of processors simultaneously.

2. Related Art

In a conventional multi-processor computer system for high end processing, adopting the heat dissipation structure designed for controlling the temperature of individual processors will seriously affect the performance of the processors due to not desirable heat transfer and heat dissipation efficiency. Referring to FIG. 1, a conventional heat dissipation structure for processors that has processor cards arranged in a unidirectional manner, and FIG. 2, another conventional heat dissipation structure that has the processor cards arranged in an opposite manner, Take a conventional multi-processor computer system that has dual processor cards as an example. FIG. 1 illustrates a computer system with eight processors that has a main board C holding four processor cards C1 and each of the processor cards C1 has two processors B. The processor cards C1 are mounted onto the main board C in a unidirectional manner. Hence the surface of the processor cards C1 wherein the processors B are located is directed towards the same direction. Moreover, the processor cards C1 are inserted respectively and vertically into a plurality of insertion ports D on the main board C at an equal interval, and on each of the processors B is installed a heat sink A respectively. FIG. 2 shows another example in which the main board C has four processor cards C2 arranged in an opposite manner since the surfaces of the processor cards C2 where the processors B are located are opposite to each other. In such a structure, the second and third processor cards C2 are close to each other while the space between the first and second processor cards C2, and the space between the third and fourth processor cards C2 are greater enough to hold the heat sink A at each processor B respectively. In the unidirectional type of dual processor cards structure the airflow aisles between the processor cards is smaller. Hence a plurality of air fans are usually installed corresponding to the airflow aisles to provide adequate airflow volume and airflow pressure to enhance heat dissipation efficiency so that airflow can pass through the heat sink to bring heat out.

However, the prior arts mentioned above have to install a heat sink for each processor and installing the heat sink individually in the limited space forming between the processor cards increases assembly cost. Moreover, as each processor has to couple with a heat sink, an additional installation space is required. Reducing the heat sink number will result in decreasing of heat transfer efficiency. Furthermore, once the heat sink is installed, the gravity center of the processor card tilts towards one side where the heat sink is installed. As a result, the processor card coupled on the insertion port of the main board also tilts towards the one side. This affects electric connection of the card interface.

### SUMMARY OF THE INVENTION

To solve the problems in the prior art, the present invention provides a heat dissipation structure for processors that can disperse heat for the processors and also couple with a plurality of processor cards in a straddling manner to enhance installation steadiness of the processor cards.

In an embodiment of the invention, a heat dissipator is coupled to a fastening element such that the heat dissipator can be mounted onto the processor card and in contact with corresponding processors to improve heat transfer of the heat dissipator.

In an embodiment of the invention, the heat dissipator couples with the processors in a contact manner through the fastening element. The concern of coupling precision is limited to the heat dissipator and the fastening element. Installation of the heat dissipator does not involve the processors. Hence total assembly and installation precision is not a big issue. This results a lower cost on assembly and installation.

In an embodiment of the invention, the fastening element and the heat dissipator are coupled through a coupling structure consisting of guiding ribs and guiding troughs. Thus assembly and installation of the heat dissipator are easier.

The heat dissipation structure for processors according to the invention aims to disperse heat for a plurality of processors located on a main board. It includes a fastening element and a heat dissipator. The fastening element has a plurality of engaging members located on the main board corresponding to the processors. The heat dissipator, made of a fine heat conductor, includes a radiator, a plurality of engaging portions and a plurality of coupling portions. The engaging portions correspond to the fastening element. The coupling portions correspond to the processors. The engaging portions are coupled with the engaging members of the fastening element. The coupling portions are in contact with the corresponding processors.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow illustration only, and thus are not limitative of the present invention, and wherein:

FIG. 1 is a perspective view of a conventional heat dissipation structure for processors with the processor cards installed in a unidirectional manner;

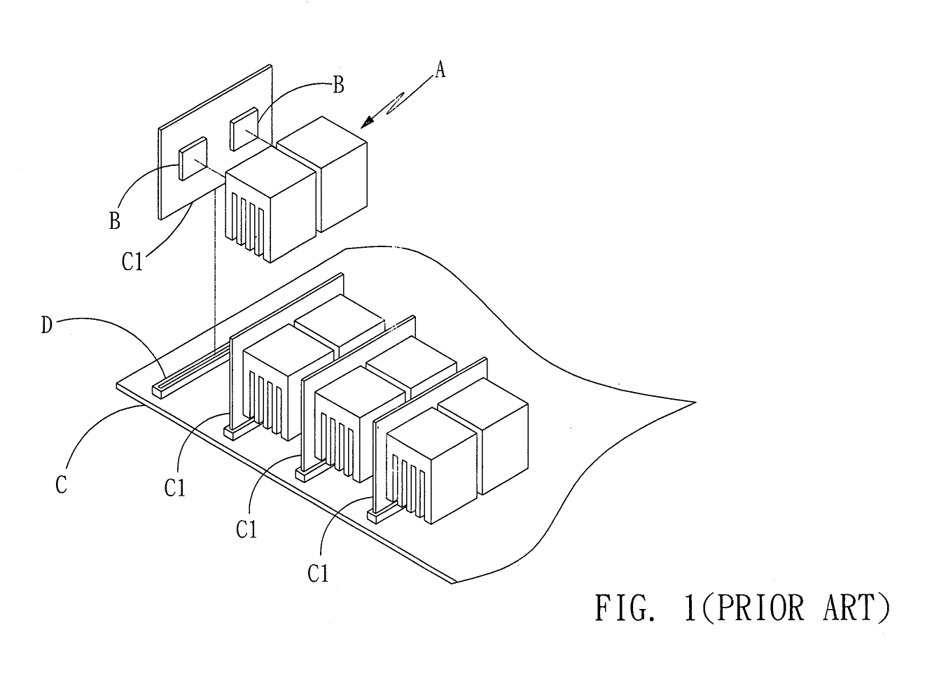

FIG. 2 is a perspective view of another conventional heat dissipation structure for processors with the processor cards installed in an opposite manner;

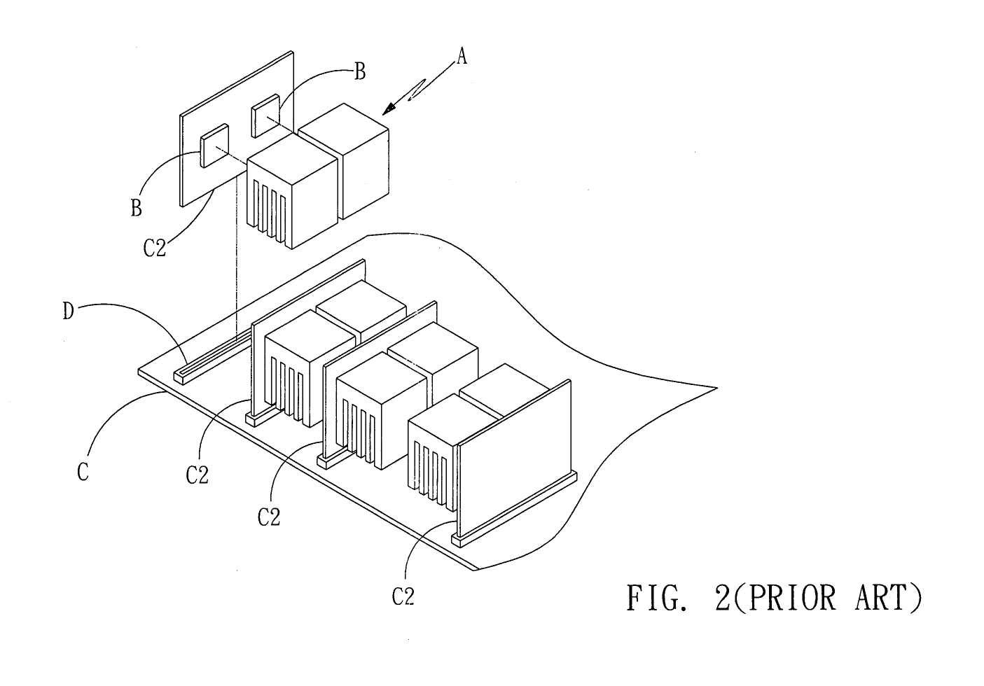

FIG. 3 is an exploded view of a first embodiment of the heat dissipation structure of the invention;

FIG. 4 is a front view according to FIG. 3 after assembled;

FIG. 5 is a top view according to FIG. 3 after assembled;

FIG. 6 is a front view of a second embodiment of the heat dissipation structure of the invention;

FIG. 7 is an exploded perspective view of a third embodiment of the heat dissipation structure of the invention;

FIG. 8 is a top view according to FIG. 7 after assembled;

FIG. 9 is a front view of a fourth embodiment of the heat dissipation structure of the invention; and

FIG. 10 is a front view of a fifth embodiment of the heat dissipation structure of the invention.

### DETAILED DESCRIPTION OF THE INVENTION

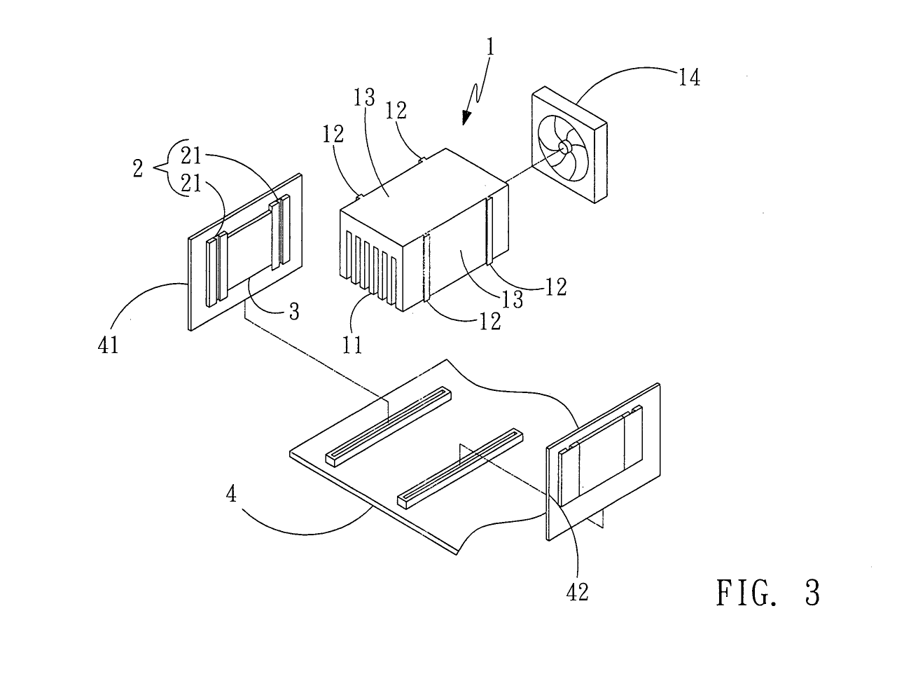

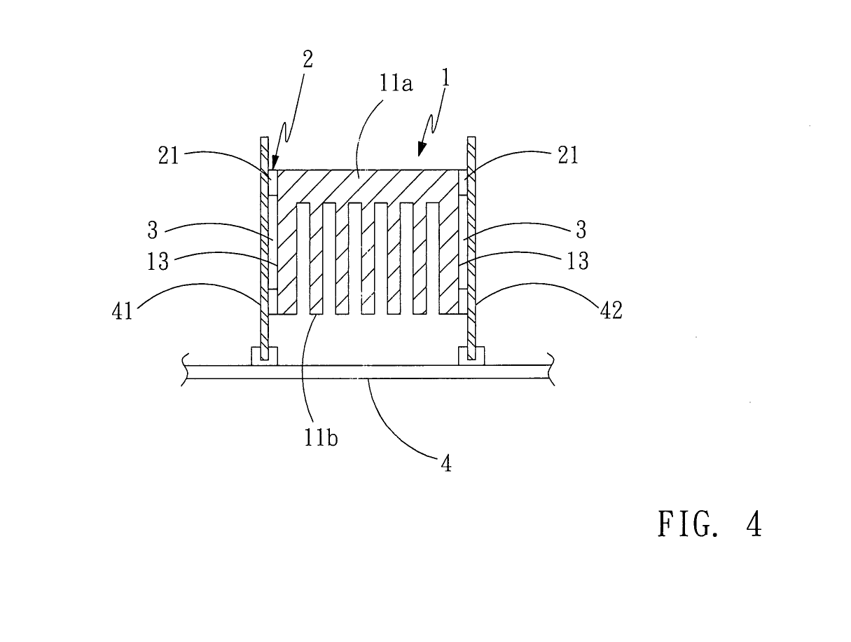

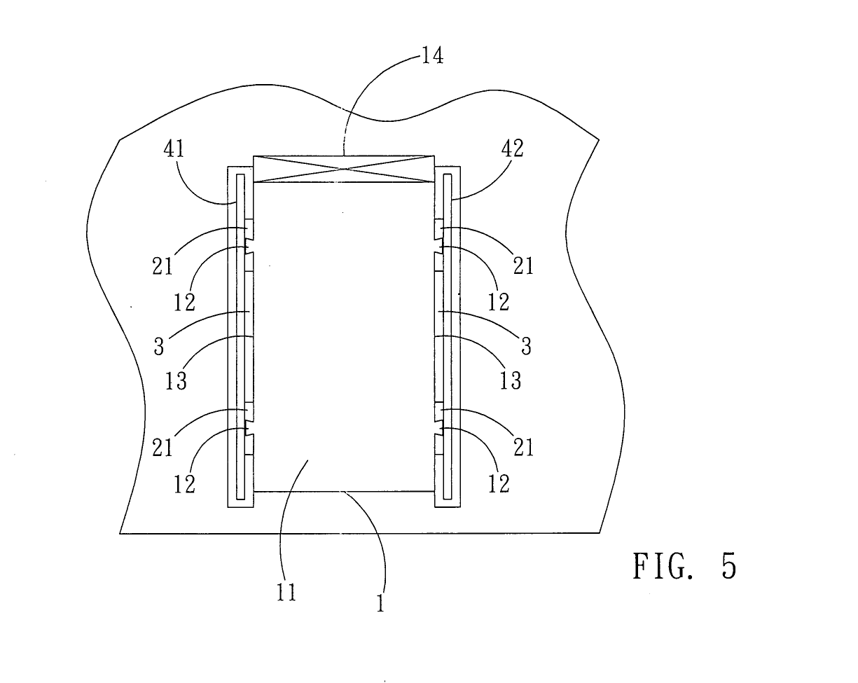

Refer to FIGS. 3, 4 and 5 for an embodiment of the heat dissipation structure of the invention. It mainly includes a heat dissipator 1 installed via a fastening element 2 to correspond to a plurality of processors 3. The heat dissipator 1 channels and disperses heat generated by the processors 3 to achieve cooling the processors 3. The fastening element 2 includes a plurality of engaging members 21 to fasten the heat dissipator 1 to be in contact with the corresponding processors 3. The processors 3 are generally high performance and mounted onto a main board 4 of a computer system, such as central processing units and processors on the peripheral interface cards.

In the embodiment set forth above, the processors 3 and the engaging members 21 are located on a first processor card 41 and a second processor card 42 to be installed on the main board 4. The first processor card 41 and the second processor card 42 have specific communication interfaces and connection interfaces to be connected electrically and mounted onto the main board 4. Moreover, the processor cards are installed on the main board 4 in a parallel manner. Thereby the fastening element 2 can fasten the corresponding heat dissipator 1 at the same time. The heat dissipator 1 includes a radiator 11, a plurality of engaging portions 12 and a plurality of coupling portions 13. The radiator 11 is made of fine heat conductor to enhance heat exchange efficiency of the heat dissipator 1 so that the processors 3 can be maintained below a safe operation temperature during operation. The engaging portions 12 correspond to the engaging members 21 of the fastening element 2 to be coupled together. The heat dissipator 1 is mounted concurrently onto the first processor card 41 and the second processor card 42. The coupling portions 13 are formed by extending a portion of the radiator 11. Each of the coupling portions 13 has a flat contact surface corresponding to each processor 3. Hence when the engaging portion 12 is coupled with the engaging member 21 the contact surface of the coupling portion 13 is in contact with the surface of the corresponding processor 3. Thereby heat generated by the processor 3 during operation is channeled by the coupling portion 13 to the radiator 11 to be dispersed to achieve heat dissipation object.

In addition, the heat dissipator 1 has at least one end surface with an air fan 14 installed thereon to generate forced air convection to enhance heat exchange between the radiator 11 and air so that heat dissipation efficiency of the radiator 11 can increase to achieve the object of heat dissipation for the processors 3.

The radiator 11 includes a heat transfer portion 11a and a plurality of heat sinks 11b. The heat sinks 11b and the coupling portions 13 are connected to the heat transfer portion 11 a so that heat on the coupling portions 13 can be transferred through the heat transfer portion 11a to the heat sinks 11b to perform heat exchange. The heat transfer portion 11a consists of a plurality of heat transfer tubes which are made of fine heat conductor and connected to the heat sinks 11b and the coupling portions 13.

Each of the engaging members 21 of the fastening element 2 has a guiding trough which is indented from the surface. Each engaging portion 12 of the heat dissipator 1 has a jutting guiding rib mating the guiding trough to form a confining sliding mechanism. Hence through the guiding trough and the guiding rib the engaging portion 12 of the heat dissipator 1 can be coupled with the corresponding engaging member 21 of the fastening element 2.

As previously discussed, the first and second processors cards 41 and 42 are mounted onto the main board 4. The processors 3 are located on the opposing surfaces of the first and second processors cards 41 and 42. Therefore the engaging members 21 of the fastening element 2 also are preferably located on the opposing surfaces of the first and second processors cards 41 and 42. On the other hand, the engaging portions 12 of the heat dissipator 1 are preferably located on two outer surfaces thereof to mate and be coupled with the engaging members 21 of the fastening element 2.

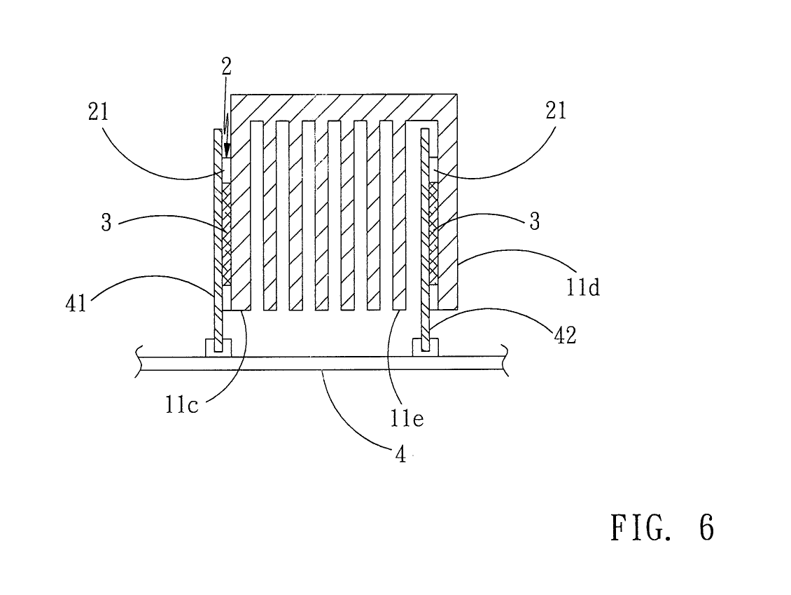

Refer to FIG. 6 for another embodiment of the invention. In this embodiment the processors 3 are located on the surfaces of the first and second processor cards 41 and 42 that face the same direction. Hence the engaging members 21 of the fastening element 2 are preferably located on the surfaces of the first and second processor cards 41 and 42 where the processors 3 are mounted. The engaging portions 12 mate the engaging members 21. Thus the engaging portions 12 on one end of the heat dissipator 1 are preferably located on an outer surface of the outmost heat sink 11c on that end while the engaging portions 12 on another end are located on an inner surface of the another outmost heat sink 11d on another end. The interval between the heat sink 11d at the outmost side and the heat sink 11e abutting the outmost side should be able to accommodate the second processor card 42.

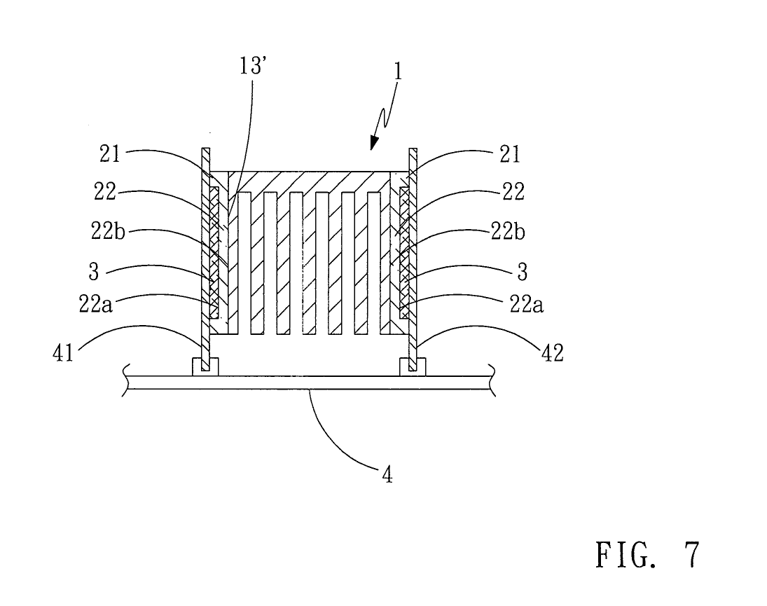

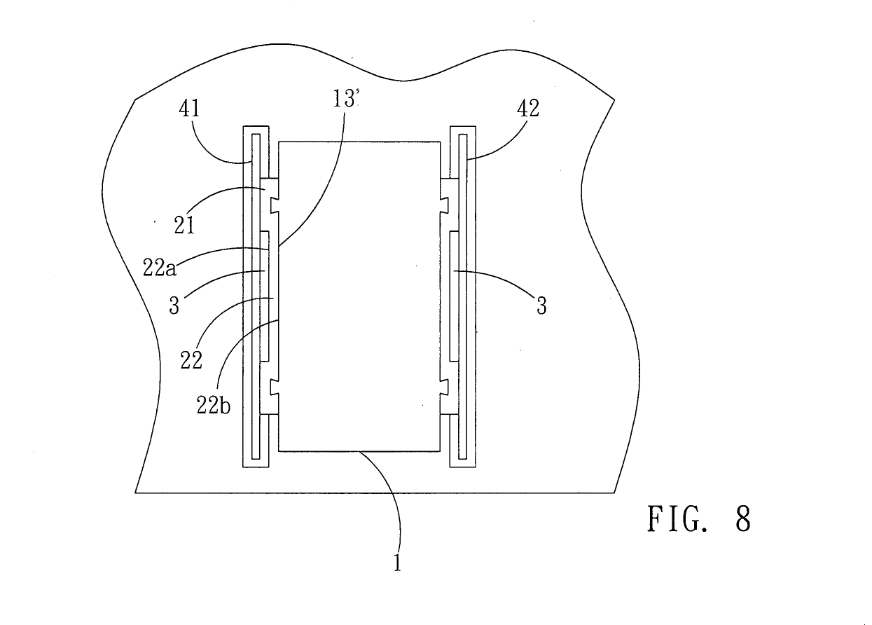

Refer to FIGS. 7 and 8 for a third embodiment of the invention. The heat dissipator 1 is located on the first processor card 41 and the second processor card 42 through the fastening element 2. The fastening element 2 has a portion serving as a heat transfer medium between the processors 3 and the heat dissipator 1 to transfer heat generated by the processors 3 during operation to the heat dissipator 1 via the fastening element 2 thereby to achieve heat dissipation effect for the processors 3.

In the third embodiment mentioned above, the fastening element 2 may have a plurality of medium layers 22 corresponding to the processors 3. The medium layers 22 are made of fine heat conductor and include a first section 22a and a second section 22b. The first section 22a mates the surface profile of a corresponding processor 3 to be in contact with the mating surface thereof. The second section 22b mates one of the coupling portions 13′ of the heat dissipator 1 to be in contact with the surface of the mating coupling surface 13′. Moreover, the contact surface of the coupling portion 13′ is a flat surface corresponding to the second section 22b. Hence after the engaging portion 12 of the heat dissipator 1 has been coupled with the engaging member 21 of the fastening element 2, the coupling portion 13a is in contact with the second section 22b to transfer heat from the processor 3 through the spacer 22 to the heat dissipator 1 to perform heat exchange with the radiator 11 to achieve cooling effect.

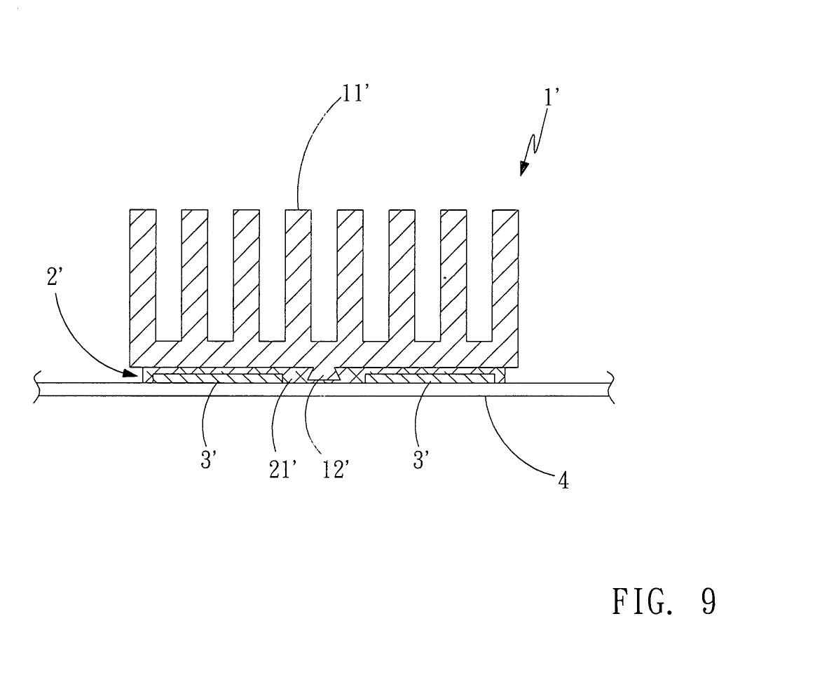

Refer to FIG. 9 for a fourth embodiment of the invention. A plurality of processors 3′ are directly mounted onto the main board 4. A fastening element 2′ with a plurality of engaging members 21′ are located on the main board 4 to mate the processors 3′. A heat dissipator 1′ with a plurality of engaging portions 12′ is provided corresponding to the engaging members 21′ of the fastening element 2. The fastening element 2′ and the heat dissipator 1′ may adopt the structures of the previous embodiments. However, the engaging portions 12′ are located on the outer surfaces of the radiator 11′. Hence through coupling of the engaging portions 12′ and the corresponding engaging members 21′ heat generated by the processors 3′ during operation can be transferred through the fastening element 2′ to the heat dissipator 1′ to achieve heat dissipation effect for the processors 3′.

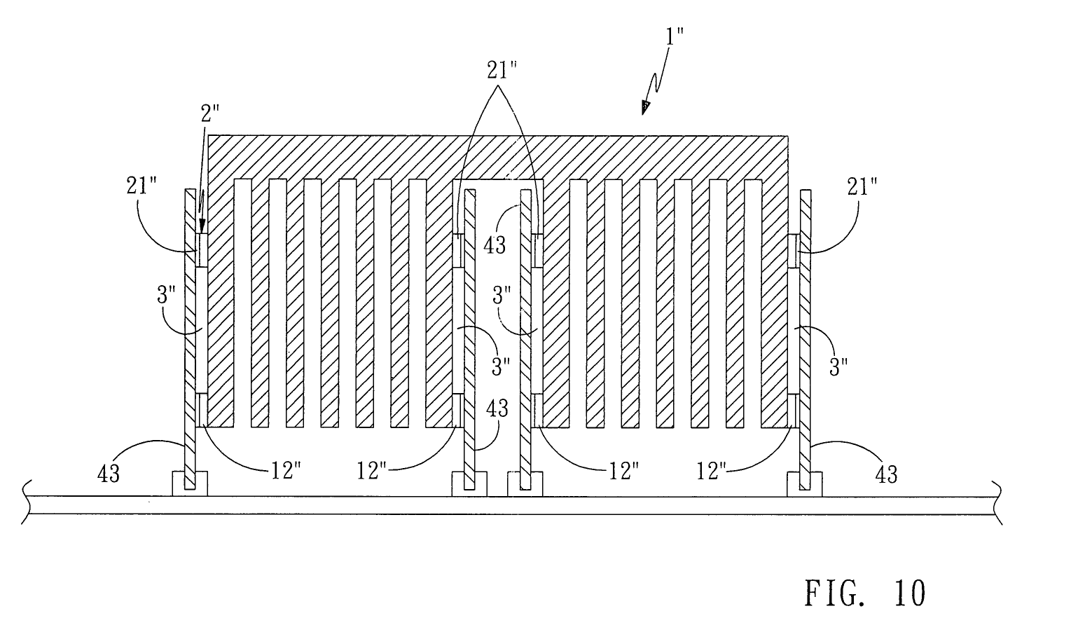

Refer to FIG. 10 for a fifth embodiment of the invention. A plurality of processors 3″ are mounted onto a plurality of processor cards 43 on the main board 4. A fastening element 2″ with a plurality-of engaging members 21″ is located on the main board 4 to mate the processors 3″. A heat dissipator 1″ with a plurality of engaging portions 12″ is provided corresponding to the engaging members 21″. The fastening element 2″ and the heat dissipator 1″ may adopt the structures of the previous embodiments. However, the heat dissipator 1″ is mounted by straddling the processor cards 43 in a manner same as the second embodiment previously discussed.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A heat dissipation structure for dispersing heat from a plurality of processors configured on a main board, comprising:
a fastening element, which has a plurality of engaging members corresponding to the processors; and
a heat dissipator, which is made of fine heat conductor and includes a radiator, a plurality of engaging portions corresponding to the fastening element and a plurality of coupling portions corresponding to the processors;
wherein the engaging portions are coupled with the engaging members and the coupling portions are in contact with the processors.

2. The heat dissipation structure of claim 1, wherein each of the engaging members and the engaging portions have respectively a guiding trough and a guiding rib mating each other to form a confining sliding mechanism, the heat dissipator being coupled with the corresponding engaging members of the fastening element through the sliding mechanism.

3. The heat dissipation structure of claim 1, wherein the fastening element further has a plurality of medium layers corresponding to the processors, each of the medium layers being made of fine heat conductor and including:
a first section corresponding to one of the processors; and
a second section corresponding to one the coupling portions;
wherein the first section is in contact with the corresponding processor and the processor also contacts with the corresponding coupling portion of the heat dissipator through the second section.

4. The heat dissipation structure of claim 3, wherein each of the engaging members and the corresponding engaging portion of the heat dissipator have respectively a guiding trough and a guiding rib mating each other to form a confining sliding mechanism, the heat dissipator being coupled with the corresponding engaging members of the fastening element through the sliding mechanism.

5. The heat dissipation structure of claim 4, wherein the processors are located on a plurality of processor cards which are mounted vertically onto the main board.

6. The heat dissipation structure of claim 5, wherein the processor cards are positioned opposite to each other and each pair of the processor cards have opposing surfaces to hold the processors.

7. The heat dissipation structure of claim 5, wherein the processor cards are installed in a unidirectional fashion and each of the processor cards has a surface facing a same direction to hold the processors.

8. The heat dissipation structure of claim 7, wherein the heat dissipator has a radiator with a plurality of heat transfer tubes.

9. The heat dissipation structure of claim 7, wherein the heat dissipator has a radiator with an air fan.

10. The heat dissipation structure of claim 4, wherein the processors are located on the main board.

11. The heat dissipation structure of claim 10, wherein the heat dissipator includes a radiator and a heat transfer portion, the radiator including a plurality of heat sinks.

12. The heat dissipation structure of claim 11, wherein the heat transfer portion includes heat transfer tubes.

13. The heat dissipation structure of claim 11, wherein the radiator includes an air fan.
